(19) United States
(12) Patent Application Publication
(10) Pub. No.: US 2007/0210409 A1
(43) Pub. Date: Sep. 13, 2007

(54) Semiconductor device including a capacitor structure and method of fabricating the same

(75) Inventors: Seok jun Won, Seoul (KR); Jung-min Park, Ansan-si (KR)

Correspondence Address: LEE & MORSE, P.C., 3141 FAIRVIEW PARK DRIVE, SUITE 500, FALLS CHURCH, VA, 22042, US

(73) Assignee: Samsung Electronics Co., Ltd.

(21) Appl. No.: 11/711,855

(22) Filed: Feb. 28, 2007

(30) Foreign Application Priority Data
Feb. 28, 2006 (KR) 10-2006-0019466

(51) Int. Cl. H01L 29/00

(52) U.S. Cl. 257/516

(57) ABSTRACT

A semiconductor device having improved capacitance may include a semiconductor substrate, a gate electrode on the semiconductor substrate, a capacitor lower electrode formed of substantially the same material as the gate electrode and being in the same layer as the gate electrode, an interlayer insulating film that covers the gate electrode and capacitor lower electrode, the interlayer insulating film including an opening through which the top surface of the capacitor lower electrode may be exposed, a capacitor upper electrode that fills the opening, and a dielectric film between the capacitor lower electrode and capacitor upper electrode.

### BACKGROUND OF THE INVENTION

1. Field of the Invention

The present invention relates to a semiconductor device including a capacitor structure and a method of fabricating the same. More particularly, the present invention relates to an analog capacitor with improved performance.

2. Description of the Related Art

Generally, system LSI (Large Scale Integration) semiconductor chips may include semiconductor devices such as an ADC (Analog to Digital Converter), which may convert analog signals input to a logic circuit to digital signals, and a DAC (Digital to Analog Converter), which may convert digital signals input to a logic circuit to analog signals.

An analog capacitor may be a unit element capable of storing information in an analog manner, by using changes in the quantity of electric charges stored as a function of an applied voltage. Voltage Coefficient of Capacitance of a capacitance (hereinafter, referred to as “VCC”) is a value that indicates changes in capacitance with respect to the applied voltage. Capacitance may become more stable as the absolute value of the VCC decreases. Therefore, an analog capacitor may preferably have a low VCC. When upper/lower electrodes are formed of polysilicon doped with N-type impurities, a negative voltage applied to the upper electrode may induce holes on the surface of the lower electrode. Accordingly, a depletion layer may be formed on the surface of the lower electrode. The width of the depletion layer may change according to the magnitude of the negative voltage. Therefore, it may be important to keep a constant interface density of a dielectric film so that the capacitance of a capacitor remains constant.

PIP (Polysilicon Insulator Polysilicon) type analog capacitors and gate electrodes may be formed by depositing polysilicon used for a gate electrode and a capacitor lower electrode, sequentially laminating a dielectric film and polysilicon for an upper electrode, and patterning the laminated structure. The formation of the gate electrodes may be completed after forming a spacer and then siliciding the resultant structure. In particular, a deterioration phenomenon of the dielectric film of the capacitor may occur while the gate electrodes and capacitors that are affected by etching undergo high-temperature thermal treatment before the spacer is formed. Due to the deterioration phenomenon of the dielectric film in which dopants of the dielectric film may diffuse due to the high temperature, it may be difficult to sustain interface density such that a leakage current may be generated.

Therefore, as the depletion area increases due to the diffusion of the dopants caused by the deterioration of the dielectric film, the VCC (Voltage Characteristic Coefficient) characteristics may deteriorate.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention is therefore directed to a semiconductor device including a capacitor and method of fabricating the same which substantially overcome one or more of the problems due to the limitations and disadvantages of the related art.

It is therefore a feature of an embodiment of the present invention to provide a method of fabricating a semiconductor device including a capacitor with improved performance.

It is therefore another feature of an embodiment of the present invention to provide a a semiconductor device including a capacitor with improved performance.

At least one of the above and other features and advantages of the present invention may be realized by providing a semiconductor device which may include a semiconductor substrate, a gate electrode which may be on the semiconductor substrate, a capacitor lower electrode which may be formed of the same layer as the gate electrode and formed of substantially a same material as the gate electrode, an interlayer insulating film which may cover the gate electrode and the capacitor lower electrode, the interlayer insulating film including an opening through which the top surface of the capacitor lower electrode is exposed, a capacitor upper electrode which may fill the opening, and a dielectric film which may be between the capacitor lower electrode and the capacitor upper electrode.

The gate electrode and the capacitor lower electrode may be formed of at least one of polysilicon doped with impurities, metal, or metal silicide. The capacitor lower electrode may have a concentration of impurities that may be substantially the same as that of the gate electrode. The capacitor lower electrode may have a concentration of impurities that may be larger than that of the gate electrode. The capacitor upper electrode may include at least one of metal nitride, tungsten, or SiGe doped with impurities. The dielectric film may be at least one of SiN, a high dielectric material, or a complex film thereof. The semiconductor device may also include contacts that may be connected to the gate electrode, the capacitor lower electrode and the capacitor upper electrode, respectively, and metal wiring lines that may be connected to the contacts.

At least one of the above and other features and advantages of the present invention may be realized by providing a method of fabricating a semiconductor device which may include forming a gate electrode and a capacitor lower electrode which may be of substantially the same material on a semiconductor substrate, the gate electrode and the capacitor lower electrode being formed of a same layer, forming an interlayer insulating film which may cover the gate electrode and the capacitor lower electrode, where the interlayer insulating film may have an opening exposing a portion of a top surface of the capacitor lower electrode, forming a dielectric film which may conform to the inside of the opening, forming a conductive film for a capacitor upper electrode which may fill the opening in which the dielectric film is formed, and planarizing until a top surface of the capacitor upper electrode may be substantially level with a top surface of the interlayer insulating film.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of a semiconductor device according to an embodiment of the present invention;

FIG. 2 illustrates a cross-sectional view of a semiconductor device according to another embodiment of the present invention;

FIGS. 3 to 5 illustrate cross-sectional sequential views of stages of a method of fabricating a semiconductor device according to an embodiment of the present invention; and

FIG. 6 illustrates a simulation graph according to an embodiment of the present invention.

### DETAILED DESCRIPTION OF THE INVENTION

Korean Patent Application No. 10-2006-0019466 filed on Feb. 28, 2006 in the Korean Intellectual Property Office, and entitled: “Semiconductor Device and Method of Fabricating the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

According to a method of fabricating a semiconductor device of the present invention, the following effects may be obtained.

First, since a high temperature thermal treatment process may be performed before the dielectric film is formed, it may be possible to prevent a phenomenon in which the dielectric film deteriorates due to high temperature.

Second, since the dielectric film may be formed at low temperature, it may be possible to maintain a high interface concentration of the dielectric film.

Third, it may be possible to increase doping concentration only in the capacitor lower electrode, without affecting the gate electrode and the resistor, in order to improve the characteristics of an interface with the dielectric film.

Fourth, deterioration of the dielectric film may be prevented, and it may thus be possible to provide stable capacitance.

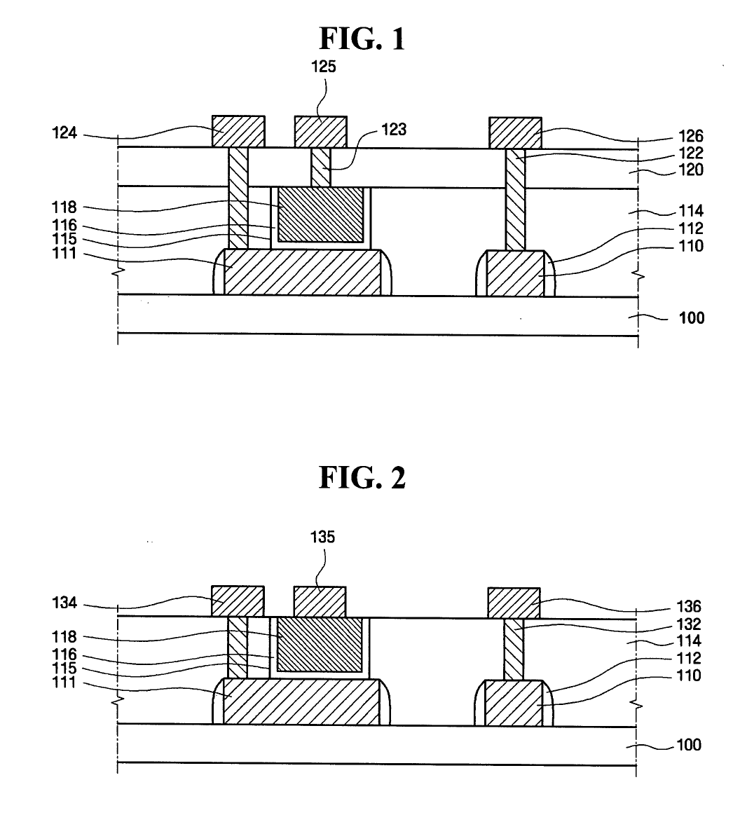

Hereinafter, a semiconductor device according to an embodiment of the present invention will be described with reference to FIG. 1. FIG. 1 illustrates a cross-sectional view of a semiconductor device according to an embodiment of the present invention.

Referring to FIG. 1, a gate electrode 110 may be formed on a semiconductor substrate 100.

A capacitor lower electrode 111 may be formed of substantially the same layer as the gate electrode 110. The gate electrode 110 and the capacitor lower electrode 111 may be formed of substantially the same materials. For example, the gate electrode 110 and the capacitor lower electrode 111 may be formed of polysilicon doped with impurities. The impurity concentration of the doped capacitor lower electrode 111 may be substantially equal to or more than that of the polysilicon gate electrode 110. However, the materials are not limited thereto, and the gate electrode 110 may be formed of at least one of, e.g., polysilicon, metal, metal silicide, etc. The gate electrode 110 may be formed of at least one of, e.g., a polysilicon electrode doped with impurities, an electrode in which a metal silicide layer is laminated on polysilicon, an electrode in which metal is laminated on polysilicon, a simple metal electrode, a simple metal silicide electrode, etc.

A spacer 112 may be formed at a sidewall of the gate electrode 110 and a sidewall of the capacitor lower electrode 111. The spacer 112 may be formed of an insulating film, e.g., a silicon nitride film (SiN), an oxide film (SiO₂), etc. The silicon nitride film may also be SiNₓ. Before forming the spacer 112, a high-temperature thermal treatment may be performed to cure damage that may occur to the gate electrode 110 and the capacitor lower electrode 111 when they are patterned.

A first interlayer insulating film 114 positioned on the semiconductor substrate 100 may cover the gate electrode 110 and capacitor lower electrode 111, and the first interlayer insulating film 114 may include an opening 115 through which a portion of the top surface of the capacitor lower electrode 111 is exposed. The first interlayer insulating film 114 is formed of, for example, O₃-TEOS (O₃-tetraethoxy orthosilane), SOG (spin-on-glass), PLD-SiO₂ (pulsed laser deposition-SiO₂), etc., but is not limited thereto. The thickness of the first interlayer insulating film 114 is in the range of about 3000 to 4000 Å, but may depart from this range.

A capacitor upper electrode 118 may be formed by filling the opening 115. The capacitor upper electrode 118 may be formed of, e.g., TiN and/or tungsten (W). However, the invention is not limited thereto, and the capacitor upper electrode 118 may include at least one metal nitrides, e.g., TiN, TaN, HFN, etc. The capacitor electrode may also be formed of, e.g., W and/or SiGe. Since the capacitor upper electrode 118 may be formed at a relatively low temperature of less than about 600° C., it may be possible to reduce any thermal deterioration of a dielectric film 116.

The dielectric film 116 may be formed between the capacitor lower electrode 111 and the capacitor upper electrode 118. The dielectric film 116 may be formed to conform to the opening 115. Accordingly, the dielectric film 116 may be formed so as to surround a side surface and bottom surface of the capacitor upper electrode 118. The dielectric film 116 may be formed of one or a composite membrane of, e.g., SiN and/or a high dielectric material.

A second interlayer insulating film 120 may be formed on the capacitor upper electrode 111 and the first interlayer insulating film 114. The second interlayer insulating film 120 may be formed using, e.g., HDP, P-TEOS, etc. The second interlayer insulating film 120 may have a thickness of, e.g., about 1000 Å.

Metal wiring lines 124 and 126 may be formed on an upper part through contacts 122 that may be connected to each of the gate electrode 110 and the capacitor lower electrode 111. Metal wiring line 125 may be formed on an upper part through short contact 123 to be connected to the capacitor upper electrode 118. The metal wiring lines 124, 125, and 126 may be formed on the second interlayer insulating film 120.

Next, a semiconductor device according to another embodiment of the present invention will be described with reference to FIG. 2. FIG. 2 illustrates a cross-sectional view of a semiconductor device according to another embodiment of the present invention.

For convenience sake, in this embodiment, the same constituent elements as those in the first embodiment may be denoted by the same reference numerals, and a detailed description thereof will not be provided.

Referring to FIG. 2, contacts 132 connected to the capacitor lower electrode 111 and the gate electrode 110 may be formed inside the first interlayer insulating film 114. Metal wiring lines 134 and 136 may be formed to be connected to the contacts 132. A metal wiring line 135 may be formed to be directly connected to the capacitor upper electrode 118 without use of a contact. In this manner, a capacitor upper electrode 118 including metal may be directly connected to the metal wiring line 135 without use of a contact.

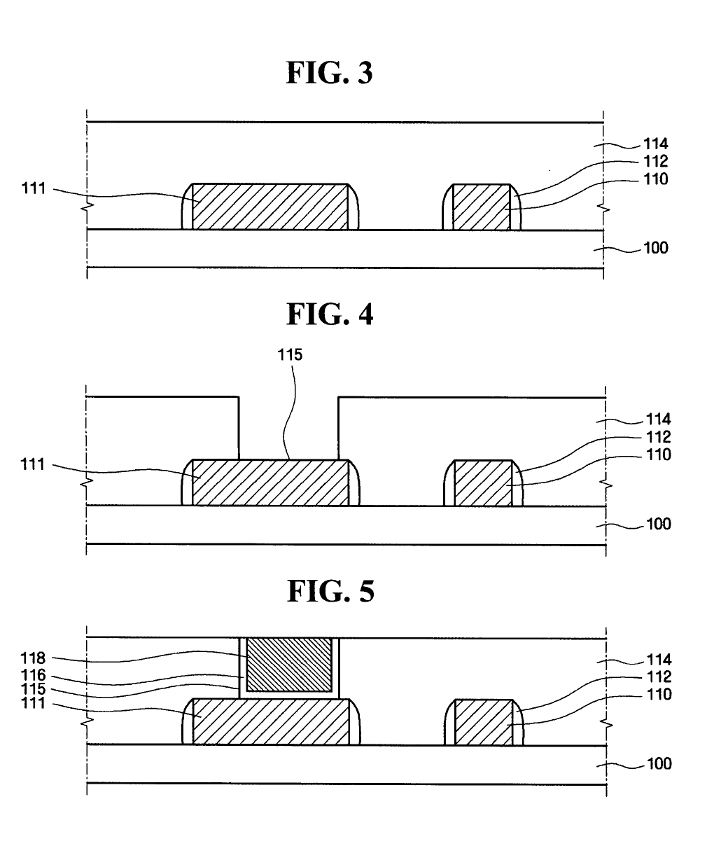

Hereinafter, stages of a method of fabricating a semiconductor device according to the first embodiment shown in FIG. 1 of the invention will be described with reference to FIGS. 3 to 5.

Referring to FIG. 3, the capacitor lower electrode 111 may be formed of substantially the same material as the gate electrode 110, and may be formed of substantially the same layer as the gate electrode. The capacitor lower electrode 111 and the gate electrode 110 may be both formed on the semiconductor substrate 100, e.g., a silicon substrate, a GaAs substrate, etc.

A polysilicon film doped with impurities may be deposited to form the gate electrode 110 and capacitor lower electrode 111 of the transistor. The polysilicon film may be formed to have a thickness in a range of, e.g., about 1500 to 2500 Å, preferably, of about 2000 Å. The polysilicon film may be formed by CVD (Chemical Vapor Deposition), SACVD (Sub-Atmospheric CVD), LPCVD (Low Pressure CVD), PECVD (Plasma Enhanced CVD), etc. Although the gate electrode 110 formed by depositing a polysilicon film may be taken as an example, the invention is not limited thereto. The gate electrode 110 may be formed of at least one selected from, e.g., polysilicon, metal, metal silicide, etc. The gate electrode 110 may be formed of at least one of, e.g., a polysilicon electrode doped with impurities, an electrode in which a metal silicide layer may be laminated on polysilicon, an electrode in which metal is laminated on polysilicon, a simple metal electrode, a simple metal silicide electrode, etc.

Subsequently, photolithography and etching may be performed on the polysilicon using a mask so that the polysilicon may be patterned, thereby forming patterns of the gate electrode 110 and the capacitor lower electrode 111. While forming the gate electrode 110, the capacitor lower electrode 111 may be formed of substantially the same material as the same layer as the gate electrode 110 without a separate process, which simplifies the manufacturing processes. In addition, although not shown, a resistor pattern may be formed of the same material as the gate electrode 110 while forming the gate electrode 110.

After the patterning, to cure damage that may occur to the gate electrode 110 or capacitor lower electrode 111 during the patterning, a thermal treatment at a temperature of more about 900° C. may be performed. The thermal treatment of more than about 900° C. may be performed after the patterning to form the gate electrode 110 and capacitor lower electrode 111, and before forming the dielectric film 116. Therefore, a subsequently deposited dielectric film may be prevented from being directly deteriorated due to high temperature.

Subsequently, a spacer 112 may be formed at a sidewall of the gate electrode 110 and a sidewall of the capacitor lower electrode 111, and siliciding may be performed. The spacer 112 may be formed of, e.g., a SiN film. The metal used for siliciding may be, e.g., Co, Ni, Ti, etc.

Subsequently, a first interlayer insulating film 114 may be formed to cover the gate electrode 110 and the capacitor lower electrode 111. The first interlayer insulating film 114 may be formed by depositing a substance using, e.g., O₃-TEOS, SOG, or PLD-SiO₂. In this case, the thickness of the first interlayer insulating film 114 may be about 4000 Å. Subsequently, a planarization CMP process may be performed on the first interlayer insulating film 114 so as to eliminate steps on the surface thereof.

Subsequently, referring to FIG. 4, an opening 115 may be formed through which a portion of the top surface of the capacitor lower electrode 111 may be exposed.

Using photolithography and etching, the opening 115 may be formed by eliminating a portion of the first interlayer insulating film 114 on the capacitor lower electrode 111 to form a capacitor region.

The doping concentration of the capacitor lower electrode 111 may be increased by injecting impurity ions in the opening 115. The characteristics of a capacitor may be improved by increasing the doping concentration of the capacitor lower electrode 111. As the doping concentration of the capacitor lower electrode 111 increases, it may be possible to provide stable capacitance with respect to voltage applied when the interface concentration between the lower electrode 111 and the dielectric film 116 increases. As a result, the VCC characteristics of the capacitor may be improved. The impurity injection concentration for increasing doping concentration may be about 1×10¹⁵/cm² or more, preferably, more than about 5×10¹⁵/cm². After injecting the impurities, activation annealing may be performed at a temperature in a range of about 600 to 700° C. for less than about five minutes. More preferably, the activation annealing may be performed at a temperature in a range of about 620 to 670° C. for less than about one minute. The thermal treatment may proceed within the temperature range in which a transistor may not deteriorate while being silicized. Otherwise, the doping concentration of the surface of the capacitor lower electrode 111 may be increased by using gas, e.g., PH₃.

In this way, the doping concentration of only the portion of the capacitor lower electrode 111 exposed through the opening 115 may be increased. Therefore, the gate electrode 110 formed on the same layer and a resistor (not shown) formed of polysilicon may not be affected. In this embodiment of the present invention, even though the doping concentration of the capacitor lower electrode 111 may be increased, the increase of the doping concentration may be an optional process, and the process may be omitted.

Next, referring to FIG. 5, the dielectric film 116 may be formed inside the opening 115, and a conductive film for a capacitor upper electrode 118 may be formed to fill the opening 115.

Referring to FIG. 5, the dielectric film 116 may be formed to conform to the entire surface of the first interlayer insulating film 114 and the inside of the opening 115. In this case, the dielectric film 116 may be formed of, e.g., a SiN-based material such as PE-SiN or LP-SiN, low temperature SiO₂, a high dielectric material formed using CVD and ALD, or formed as a complex film thereof, etc. When the dielectric film 116 is formed by LP-SiN deposition, it may be deposited at a temperature of below about 680° C. However, when the dielectric film 116 is formed by PE-SiN deposition, it may be deposited at a temperature of below about 550° C. When the dielectric film 116 is deposited at a lower temperature, the membrane of the dielectric film 116 may be further improved.

After the dielectric film 116 is formed, a thermal treatment may be performed on the dielectric film for less than about 10 minutes in an atmosphere including O₂ at a temperature of below about 650° C. The membrane of the dielectric film 116 may be further improved by the thermal treatment.

A conductive film for a capacitor upper electrode may be formed of any one of, e.g., metal nitride material, tungsten, SiGe, a compound thereof, etc. In particular, the capacitor upper electrode 118 may be formed of, e.g., TiN and/or tungsten. The deposition temperature for metal nitride systems may be below about 600° C. or below about 500° C. Among the various methods of deposition, CVD may be performed at a temperature in a temperature range of about 450 to 500° C., and ALD may be performed at a temperature in a range of about 250 to 400° C. SiGe may be made of doped polysilicon containing Ge, and may be capable of undergoing a process at a temperature of below about 600° C., more preferably, below about 500° C.

In this manner, compared to the general technology in which the capacitor upper electrode 118 may be a simple polysilicon electrode, deposition may be performed at a relatively low temperature of below about 600° C., thereby preventing thermal deterioration phenomena from occurring.

Next, planarization may be performed, so that the surface of the capacitor upper electrode 118 may be substantially level with the top surface of the first interlayer insulating film 114.

Referring again to FIG. 1, after completing the formation of the capacitor upper electrode 118, the contacts 122 may be formed to be respectively connected to the gate electrode 110 and the capacitor lower electrode 111. The short contact 123 may be connected to the capacitor upper electrode 118. The metal wiring lines 124, 125, and 126 may be formed to be connected to the contacts 122 and 123.

The second interlayer insulating film 120 may be deposited on a structure in which the formation of capacitor upper electrode 118 may be completed. The second interlayer insulating film 120 may be formed using, e.g., HDP, P-TEOS, etc. The second interlayer insulating film may be easy to planarize and may not readily absorb moisture. The second interlayer insulating film 120 may be formed to have a thickness of about 1000 Å. A conductive material may fill the contact hole formed through the second interlayer insulating film 120 and the first interlayer insulating film 114, and thus the contacts 122 may be formed on the capacitor lower electrode 111 and the gate electrode 110. In addition, a conductive material may fill the contact hole formed through the second interlayer insulating film 120, and thus the short contact 123 may be formed on the capacitor upper electrode 118. Subsequently, the metal wiring lines 124, 125, and 126 may be formed to be connected to the contacts 122 and 123.

Referring to FIG. 2, stages of a method of fabricating a semiconductor device according to another embodiment of the present invention will be described.

The processes for forming the capacitor lower electrode 111, the dielectric film 116 and the capacitor upper electrode 118 to complete the formation of the capacitor may be the same as the first embodiment. For this reason, only a metal wiring line process that may be a subsequent process will be described.

After forming the capacitor upper electrode 118, the contacts 132 may be formed to be connected to the gate electrode 110 and the capacitor lower electrode 111, respectively.

Contact holes to connect the gate electrode 110 and the capacitor lower electrode 111 with the upper metal wiring lines may be formed by etching a predetermined region of the first interlayer insulating film 114. The contacts 132 may be formed by filling the contact holes with conductive material. Then, the metal wiring lines 134 and 136 may be connected to the contacts 132, and the metal wiring line 135 may be directly connected to the capacitor upper electrode 118. Since the capacitor upper electrode 118 may be an electrode including metal, the electrode may be directly connected to the metal wiring line 135 without utilizing a contact.

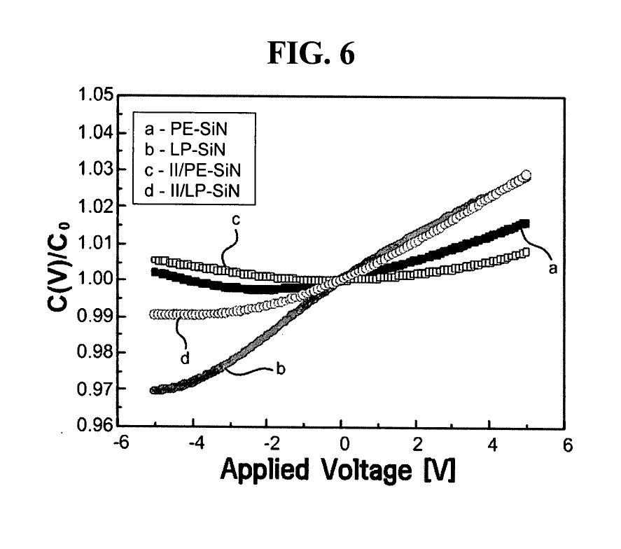

FIG. 6 illustrates a simulation graph of the dielectric 116 according to the first embodiment of the present invention.

In the graph, the X-axis represents an applied voltage and the Y-axis represents a capacitance normalized with respect to 1 when no voltage is applied.

In FIG. 6, “a,” “b,” “c,” and “d” indicate the results of different methods of forming a dielectric film.

In FIG. 6, “a” refers to a case in which the dielectric film 116 may be deposited by a PE-SiN method, “b” refers to a case in which the dielectric film 116 may be deposited by a LP-SiN method, “c” refers to a case in which the dielectric film 116 may be deposited by a PE-SiN method after injecting ions (II) into the capacitor lower electrode 111, and “d” refers to a case in which the dielectric film 116 may be deposited by a LP-SiN method after injecting ions (II) into the capacitor lower electrode 111.

Referring to FIG. 6, significant differences between case “a” (PE-SiN) and case “b” (LP-SiN), that is, differences between deposition methods using different temperatures, are demonstrated. When the dielectric film 116 is deposited by PE-SiN, which may be performed at a low temperature of about 550° C., VCC curve “a” shows more gradual curvature than VCC curve “b.” This demonstrates that stable capacitance may be provided regardless of changing applied voltage.

In addition, when curves “a” and “c” are compared to each other or when b and d are compared to each other, differences in whether ion injection may be selectively performed on the capacitor lower electrode 111 are demonstrated. In cases “c” and “d,” when ions are injected into the capacitor lower electrode 111, the characteristics of an interface with the dielectric film 116 may be improved by increasing the doping concentration, thereby obtaining a VCC characteristic curve in which curves “c” and “d” have more gradual curvature than curve “b.” However, as shown in FIG. 6, when the dielectric film 116 may be formed by a low temperature deposition method PE-SiN (curve a), the most significant stability effect may be shown in the graph.

A high temperature thermal treatment of more than about 900° C. may be performed before the dielectric film 116 is formed, which may prevent the dielectric film 116 from deteriorating due to high temperature. When the dielectric film 116 is formed by a low temperature deposition method, the deterioration phenomenon may be prevented. In addition, benefits may be found when fabricating a semiconductor device in which the doping concentration may be increased only in the polysilicon capacitor lower electrode 111.

In this manner, by preventing the deterioration phenomenon of the dielectric film 116, impurities may be prevented from diffusing due to high temperature. Moreover, by selectively increasing the doping concentration of the capacitor lower electrode 111, the characteristics of an interface with the dielectric film 116 may be improved. Therefore, it may be possible to provide stable capacitance even when the applied voltage is changed or varied.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a semiconductor substrate;
a gate electrode on the semiconductor substrate;
a capacitor lower electrode formed on a same layer as the gate electrode and formed of substantially a same material as the gate electrode;
an interlayer insulating film covering the gate electrode and the capacitor lower electrode, the interlayer insulating film including an opening through which a top surface of the capacitor lower electrode is exposed;
a capacitor upper electrode filling the opening; and
a dielectric film between the capacitor lower electrode and the capacitor upper electrode.

2. The semiconductor device as claimed in claim 1, wherein the gate electrode and the capacitor lower electrode are formed of at least one of polysilicon doped with impurities, metal, or metal silicide.

3. The semiconductor device as claimed in claim 2, wherein the gate electrode and the capacitor lower electrode are formed of polysilicon doped with impurities, and the capacitor lower electrode has a concentration of impurities that is substantially the same as that of the gate electrode.

4. The semiconductor device as claimed in claim 2, wherein the gate electrode and the capacitor lower electrode are formed of polysilicon doped with impurities, and the capacitor lower electrode has a concentration of impurities that is larger than that of the gate electrode.

5. The semiconductor device as claimed in claim 1, wherein the capacitor upper electrode comprises at least one of metal nitride, tungsten, or SiGe doped with impurities.

6. The semiconductor device as claimed in claim 1, wherein the dielectric film is any one of SiN, a high dielectric material, or a complex film thereof.

7. The semiconductor device as claimed in claim 1, further comprising:
contacts connected to the gate electrode, the capacitor lower electrode and the capacitor upper electrode, respectively; and
metal wiring lines connected to the contacts.

8. The semiconductor device as claimed in claim 1, further comprising:
contacts connected to the gate electrode and the capacitor lower electrode, respectively; and
metal wiring lines connected to the contacts and directly connected to the capacitor upper electrode.

9. A method of fabricating a semiconductor device, comprising:
forming a gate electrode and a capacitor lower electrode of substantially a same material on a semiconductor substrate, the gate electrode and the capacitor lower electrode being formed of a same layer;
forming an interlayer insulating film covering the gate electrode and the capacitor lower electrode, the interlayer insulating film having an opening exposing a portion of a top surface of the capacitor lower electrode;
forming a dielectric film conforming to an inside of the opening;
forming a conductive film for a capacitor upper electrode which fills the opening in which the dielectric film is formed; and
planarizing until a top surface of the capacitor upper electrode is substantially level with that of the interlayer insulating film.

10. The method as claimed in claim 9, wherein the gate electrode and the capacitor lower electrode are formed of at least one of polysilicon doped with impurities, metal or metal silicide.

11. The method as claimed in claim 9, further comprising:
injecting impurities into the top surface of the capacitor lower electrode exposed through the opening of the interlayer insulating film, before forming the dielectric film.

12. The method as claimed in claim 9, wherein the capacitor upper electrode is any one of metal nitride material, tungsten, SiGe doped with impurities, or a compound thereof.

13. The method as claimed in claim 9, wherein the capacitor upper electrode is formed at a temperature of below about 600° C.

14. The method as claimed in claim 9, wherein the dielectric film is formed of at least one of SiN, high dielectric material, or a complex film thereof.

15. The method as claimed in claim 9, wherein the dielectric film is formed at a temperature of below about 650° C.

16. The method as claimed in claim 9, further comprising:
performing a thermal treatment on the dielectric film in an atmosphere including O₂ at a temperature of below about 650° C., after forming the dielectric film.

17. The method as claimed in claim 9, further comprising:
forming contacts to be connected to the gate electrode, the capacitor lower electrode and the capacitor upper electrode, respectively, after completing the formation of the capacitor upper electrode; and
forming metal wiring lines to be connected to the contacts.

18. The method as claimed in claim 9, after completing the formation of the capacitor upper electrode, further comprising:
forming contacts to be connected to the gate electrode and the capacitor lower electrode, respectively; and
forming metal wiring lines to be connected to the contacts and to be directly connected to the capacitor upper electrode.

19. The method as claimed in claim 9, further comprising:
performing a thermal treatment of more than about 900° C., after patterning to form the gate electrode and the capacitor lower electrode.
